(19) United States
(12) Patent Application Publication
(10) Pub. No.: US 2024/0063107 A1
(43) Pub. Date: Feb. 22, 2024

(54) CRACK ARREST FEATURES FOR MIULTILEVEL PACKAGE SUBSTRATE

(71) Applicant: Texas Instruments Incorporated, Dallas, TX (US)

(72) Inventors: Jason Colte, La Trinidad (PH); Jerry Cayabyab, Angeles City (PH); Julian Carlo Barbadillo, Mabalacat City (PH); John Carlo Molina, Limay (PH); Richard Sumalinog, San Pablo (PH); Raust Glenn Magcaling, Central Luzon (PH); Ruby Ann Camenforte, Pampanga (PH)

(21) Appl. No.: 17/892,202

(22) Filed: Aug. 22, 2022

(51) Int. Cl. H01L 23/498; H01L 21/48; H01L 23/00; H01L 21/56

(52) U.S. Cl. CPC H01L 23/49838; H01L 23/49822; H01L 21/4857; H01L 24/16; H01L 24/81; H01L 24/13; H01L 21/561; H01L 2224/13147; H01L 2224/16227; H01L 2224/81815

(57) ABSTRACT

An electronic device includes a multilevel package substrate, a semiconductor die mounted to the multilevel package substrate, and a package structure that encloses the semiconductor die and a portion of the multilevel package substrate. The multilevel package substrate has a first level, a second level, a first metal stack, and a second metal stack. The first metal stack includes a first set of contiguous metal structures of the first and second levels, the second metal stack includes a second set of contiguous metal structures of the first and second levels, the first and second metal stacks are spaced apart from one another, a first metal trace of the first metal stack partially overlaps a second metal trace of the second metal stack, and the first and second metal traces are in different levels of the multilevel package substrate.

### BACKGROUND

Multilevel routing structures or package substrates are sometimes used for signal and power routing in packaged electronic devices. Substrate cracking can occur in multilevel package substrates, for example, along saw cutting lines and between adjacent metal stacks due to rigidity and high die attach pad area. Cracks in the substrate insulator material can cause various problems including degraded device electrical performance during operation, and cracking during molding can lead to over mold or mold bleed defects in the packaged device. Substrate cracking can be addressed somewhat by reducing the mold height to reduce the mold material volume and lessen the force applied to the multilevel package substrate during mold filling operations. However, some device designs require thick molded package structures to provide a desired level of electrical insulation and to accommodate tall dies and/or passive components and reducing the mold height is not an option in some cases.

### SUMMARY

In one aspect, an electronic device includes a multilevel package substrate, a semiconductor die mounted to the multilevel package substrate, and a package structure that encloses the semiconductor die and a portion of the multilevel package substrate. The multilevel package substrate has a first level, a second level, a first metal stack, and a second metal stack. The first metal stack includes a first set of contiguous metal structures of the first and second levels, the second metal stack includes a second set of contiguous metal structures of the first and second levels, the first and second metal stacks are spaced apart from one another, a first metal trace of the first metal stack partially overlaps a second metal trace of the second metal stack, and the first and second metal traces are in different levels of the multilevel package substrate.

In another aspect, a multilevel package substrate includes a first level, a second level, a first metal stack including a first set of contiguous metal structures of the first and second levels, and a second metal stack including a second set of contiguous metal structures of the first and second levels, the second metal stack spaced apart from the first metal stack. A first metal trace of the first metal stack partially overlapping a second metal trace of the second metal stack, and the first and second metal traces are in different levels of the multilevel package substrate.

In a further aspect, a method includes fabricating a multilevel package substrate having a first level, a second level, a first metal stack, and a second metal stack, the first metal stack including a first set of contiguous metal structures of the first and second levels, the second metal stack including a second set of contiguous metal structures of the first and second levels, the first and second metal stacks spaced apart from one another, a first metal trace of the first metal stack partially overlapping a second metal trace of the second metal stack, and the first and second metal traces in different levels of the multilevel package substrate.

### BRIEF DESCRIPTION OF THE DRAWINGS

FIG. 1 is a top perspective view of a packaged electronic device with a multilevel package substrate with interleaved traces of adjacent metal stacks.

FIG. 1A is a sectional side elevation view of the electronic device along line 1A-1A of FIG. 1.

FIG. 2 is a flow diagram of a method of making an electronic device.

FIGS. 3-15 are partial sectional side elevation views illustrating fabrication of a multilayer substrate for the electronic device of FIG. 1.

FIG. 16 is a partial sectional side elevation view of die attach processing in fabrication of the electronic device of FIG. 1.

FIG. 17 is a partial sectional side elevation view of solder reflow processing in fabrication of the electronic device of FIG. 1.

FIG. 18 is a partial sectional side elevation view of mold processing in fabrication of the electronic device of FIG. 1.

FIG. 19 is a partial sectional side elevation view of package separation processing in fabrication of the electronic device of FIG. 1.

FIG. 20 is a top perspective view of another packaged electronic device with a multilevel package substrate with interleaved traces of adjacent metal stacks.

FIG. 20A is a sectional side elevation view of the electronic device along line 20A-20A of FIG. 20.

FIG. 21 is a top perspective view of yet another packaged electronic device with a multilevel package substrate with interleaved traces of adjacent metal stacks.

FIG. 21A is a sectional side elevation view of the electronic device along line 21A-21A of FIG. 21.

FIG. 22 is a top perspective view of still another packaged electronic device with a multilevel package substrate with interleaved traces of adjacent metal stacks.

FIG. 22A is a sectional side elevation view of the electronic device along line 22A-22A of FIG. 22.

FIG. 23 is a sectional side elevation view of a system with the electronic device of FIG. 1 soldered to a host printed circuit board.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about,” “approximately,” or “substantially” preceding a value means+/−10 percent of the stated value. One or more operational characteristics of various circuits, systems and/or components are hereinafter described in the context of functions which in some cases result from configuration and/or interconnection of various structures when circuitry is powered and operating.

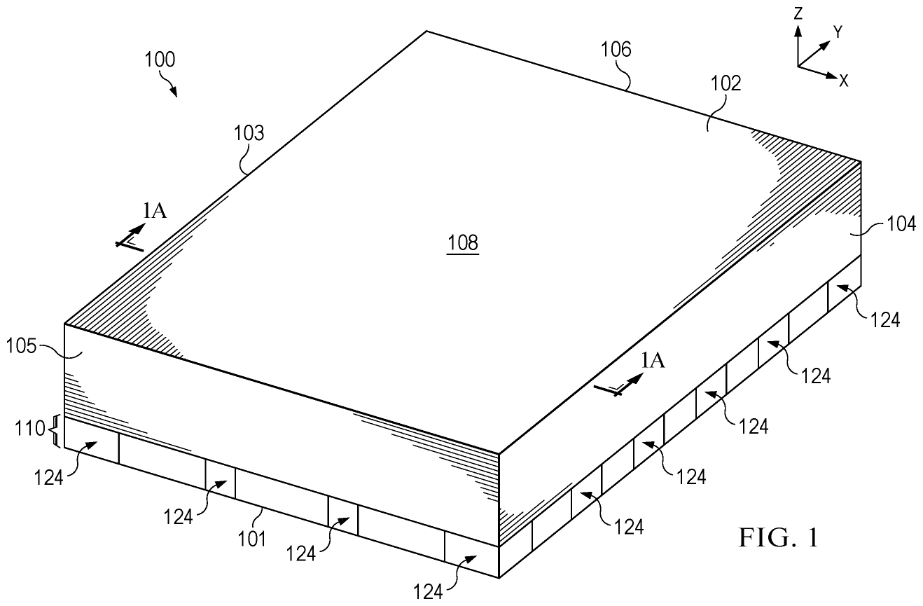

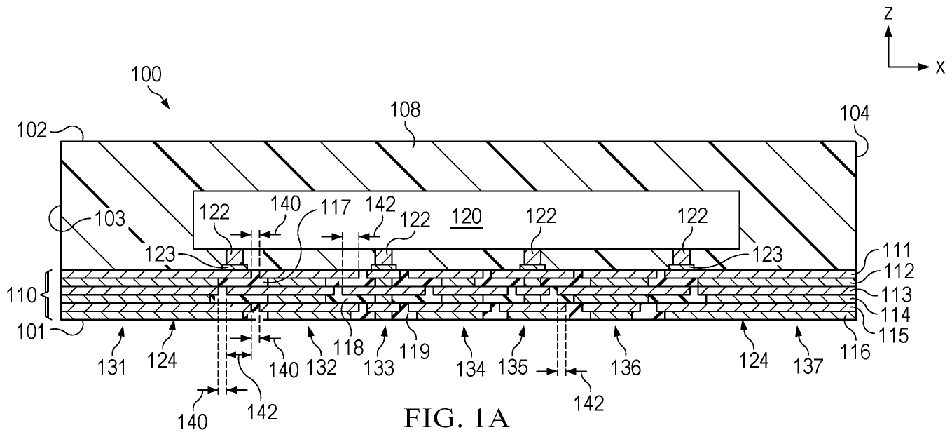

FIGS. 1 and 1A show top perspective and sectional side views of a packaged electronic device 100 with a multilevel package substrate 110 having interleaved overlapping traces of adjacent metal stacks to mitigate cracks and crack propagation and add structural strength reinforcement in the multilevel package substrate 110. The electronic device 100 is shown in FIGS. 1 and 1A in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. The electronic device 100 has a package structure 108, such as a molded plastic, and the electronic device has opposite first and second (e.g., bottom and top) sides 101 and 102, respectively, which are spaced apart from one another along the third direction Z. The package structure 108 and the electronic device 100 have laterally opposite third and fourth sides 103 and 104 spaced apart from one another along the first direction X, and opposite fifth and sixth sides 105 and 106 spaced apart from one another along the second direction Y in the illustrated orientation. The sides 101-106 in one example have substantially planar outer surfaces. In other examples, one or more of the sides 101-106 have curves, angled features, or other non-planar surface features.

As best shown in FIG. 1A, the multilevel package substrate 110 has three levels in a stacked arrangement along the third direction Z. In this example, the individual levels have conductive metal features that form upper patterned traces and lower vias, as well as electrical insulator material that extends between and around the conductive metal features. In one example, the conductive metal features of the individual levels are or include copper. In another example, the conductive metal features are or include aluminum or other suitable electrically conductive metal material. In the illustrated example, the upper or first level includes patterned metal traces 111, metal vias 112, and compression molded insulator material 117 that extends between and around the traces 111 and the vias 112. A middle or second level includes patterned metal traces 113, metal vias 114, and compression molded insulator material 118 that extends between and around the traces 113 and the vias 114. The first level 111, 112, 117 extends in a first plane of the respective first and second directions X and Y and the second level 113, 114, 118 extends in a second plane of the first and second directions X and Y, and the first and second planes are spaced apart from one another along the third direction Z. In this example, a bottom or third level includes patterned metal traces 115, metal vias 116, and compression molded insulator material 119 that extends between and around the traces 115 and the vias 116, and the third level 115, 116, 119 extends in a third plane of the first and second directions X and Y.

The electronic device 100 includes a semiconductor die 120 (FIG. 1A) mounted to the top side of the first level of the multilevel package substrate 110. The semiconductor die 120 includes conductive metal features 122 that operate as terminals for electrical connection of circuitry within the semiconductor die 120 and traces of the multilevel package substrate 110. In one example, the conductive features 122 are copper or other conductive metal formed as bond pads suitable for bond wire connection in the electronic device 100. In the illustrated example, the conductive features 122 are copper pillars and the semiconductor die 120 is flip chip attached to the top side of the first level of the multilevel package substrate 110, with the conductive features 122 soldered to the top sides of select metal traces 111 by solder 123 to provide electrical connection of the semiconductor die 120 to conductive features of the multilevel package substrate 110.

As further shown in FIG. 1, the multilevel package substrate 110 includes conductive features that form or operate as leads 124 suitable for soldering to a host printed circuit board (PCB, not shown). The multilevel package substrate 110 provides interconnection routing between an electronic component or components of the semiconductor die 120 and the leads 124. In certain implementations, moreover, the electronic device 100 can include further electronic components (not shown), such as one or more additional semiconductor dies, passive circuit components (e.g., resistors, capacitors, inductors, etc.) to form one or more circuits with suitable electrical connections to one or more of the leads 124. The illustrated electronic device 100 is a quad flat no-lead (QFN) type packaged electronic device having leads 124 with exposed bottom sides along the first side 101 of the electronic device 100, and exposed conductive sidewalls. Different lead types and package types can be used in different implementations, including leads that extend outward from one or more lateral sides 103-106 (e.g., gullwing leads, J leads, etc.), as well as ball grid array (BGA) terminals disposed along the bottom or first side 101 of the electronic device 100 to facilitate soldering to a host PCB.

The leads 124 and other conductive features of the multilevel package substrate 110 form metal stacks that include contiguous metal structures of two or more of the levels of the multilevel package substrate 110. The electronic device 100 can have any number of metal stacks in the multilevel package substrate 110. FIG. 1A illustrates example metal stacks 131, 132, 133, 134, 135, 136 and 137. In this example, each of the illustrated metal stacks 131-137 include a corresponding set of contiguous metal structures of all three levels. In other examples, one or more of the metal stacks include contiguous metal structures of fewer than all the levels of the multilevel package substrate 110. In the illustrated example, the first and seventh metal stacks 131 and 137 extend along the respective third and fourth sides 103 and 104 and form corresponding ones of the leads 124 of the electronic device 100.

The multilevel package substrate 110 advantageously provides interleaved overlapping traces in one or more pairs of adjacent or neighboring metal stacks. The overlap of metal traces in certain implementations helps to mitigate crack formation and/or crack propagation in the insulator material 117, 118, and/or 119 of the multilevel package substrate 110. The adjacent or neighboring metal stacks are spaced apart from one another, and may, but need not be, electrically connected to one another in the multilevel package substrate 110 As shown in FIG. 1A, for example, the respective first and second metal stacks 131 and 132 are spaced apart from one another along the first direction X and are not electrically connected to one another. In one implementation, the metal stacks 131-137 are spaced apart from one another in both the first and second directions X and Y, respectively. The first metal stack 131 in this example includes a first set of contiguous metal structures formed by patterned metal of the metal traces 111, 113, and 115 and the vias 112, 114, and 116. In the illustrated example, the second metal stack 132 includes a second set of contiguous metal structures formed by the patterned metal of the metal traces 111, 113, and 115 and the vias 112, 114, and 116. The other illustrated metal stacks 133-137 in this example include corresponding sets of contiguous metal structures formed by patterned metal of the metal traces 111, 113, and 115 and the vias 112, 114, and 116. In other implementations, one or more of the metal stacks can include sets of contiguous metal structures formed by patterned metal of fewer than all of the metal traces and/or vias.

In the illustrated example, a first metal trace 111 of the first metal stack in the first level of the multilevel package substrate 110 partially overlaps a second metal trace 113 of the second metal stack 132 in the second level of the multilevel package substrate 110. In this example, a metal trace 115 of the first metal stack and the third level of the multilevel package substrate 110 partially overlaps the second metal trace 113 of the second metal stack 132 and the second level. Similar metal trace partial overlap is seen in the other adjacent or neighboring pairs of metal stacks 131-137 in the example of FIG. 1A.

As used herein, partial overlap means that two or more given traces of neighboring or adjacent metal stacks in the multilevel package substrate 110 a respectively above and below one another such that a line along the third direction Z normal to the planes of the levels of the multilevel package substrate 110 intersects the two or more given traces. This feature mitigates or prevents cracks and/or crack propagation in the insulator material 117-119 of the multilevel package substrate 110 by reducing or eliminating crack propagation paths along the third direction Z. Instead, the partial overlap causes potential crack propagation paths to deviate from the third direction Z, and the illustrated examples require any crack to propagate through a full or partial serpentine path. This feature advantageously reduces or avoids cracks and associated over mold or mold bleed problems during fabrication of the electronic device 100. Although the illustrated sectional line along line 1A-1A of FIGS. 1 and 1A illustrates a partial overlapping of metal traces in different levels in adjacent metal stacks 131-137 along the first direction X, similar features are provided along the second direction Y and other directions in a plane of the first and second directions X and Y, respectively.

The example electronic device 100 of FIGS. 1 and 1A also incorporates controlled spacing of trace and via features within the individual levels, in which the metal structures of the metal stacks 131-137 are spaced apart from one another by a non-zero spacing distance 140. For example, the metal traces of the first and second metal stacks 131 and 132 are spaced apart from one another in the respective first and second planes by a spacing distance 140. In one or more implementations, the metal structures of the neighboring or adjacent metal stacks are spaced apart from one another by a spacing distance 140 that is greater than or equal to 30 μm and less than 50 μm. Manufacturing limitations regarding feature size and spacing can allow spacing distances 140 of less than 30 μm in certain implementations, for example, down to 20 μm or even 15 μm in certain examples. Increasing the spacing distances 140 beyond about 50 μm is possible in these or other examples, but excessive spacing distances 140 can increase the possibility of cracks and/or crack propagation. In the illustrated example, several examples of trace spacing distances 140 are indicated in FIG. 1A, and larger capital X-Y plane spacing distances between metal via features of the multilevel package substrate 110 may result from the fabrication processing technology used in making the multilevel package substrate 110, for example, in which via structures of a given level are generally narrower than the corresponding trace features of the given level.

In addition, the overlapping metal traces of the adjacent or neighboring metal stacks 131-137 overlap one another by a non-zero overlap distance 142. In one implementation, the overlap distance 142 is greater than the spacing distance 140. In this or another example, the overlap distance 142 is greater than or equal to 25 μm. Overlap distances 142 less than 25 μm can be used but may increase the linearity of crack propagation paths through the insulator material 117-119 of the multilevel package substrate 110. Increasing the overlap distances 142 can help mitigate or prevent cracks and/or crack propagation in the insulator material 117-119, but practical limits to the overlap distances 142 may arise in specific designs, for example, due to limited X-Y plane spacing requirements for the overall dimensions of the electronic device 100.

As further shown in FIGS. 1 and 1A, the molded package structure 108 encloses the semiconductor die 120 and an upper portion of the multilevel package substrate 110. In other implementations, the molded package structure 108 can enclose further portions of the multilevel package substrate 110, for example, along one or more of the lateral sides 103-106. The illustrated example allows solder wicking along exposed side portions of the leads 124, for example, in QFN or other package types and applications, to facilitate optical inspection of solder joints, etc.

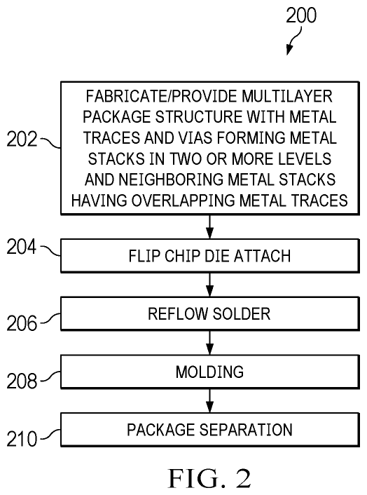

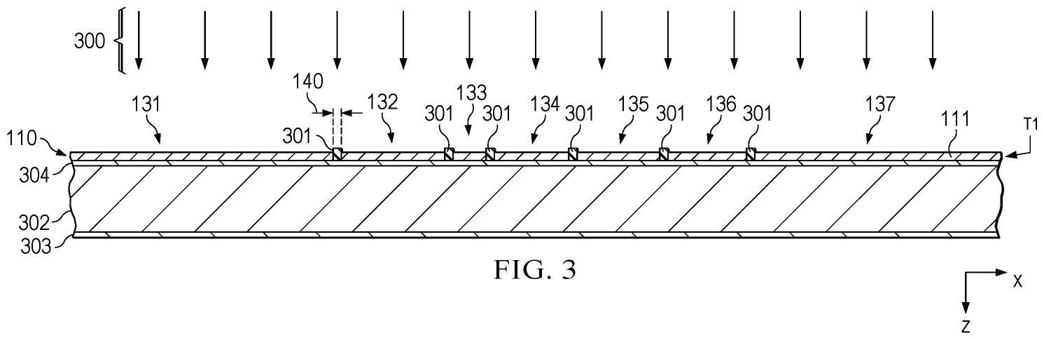

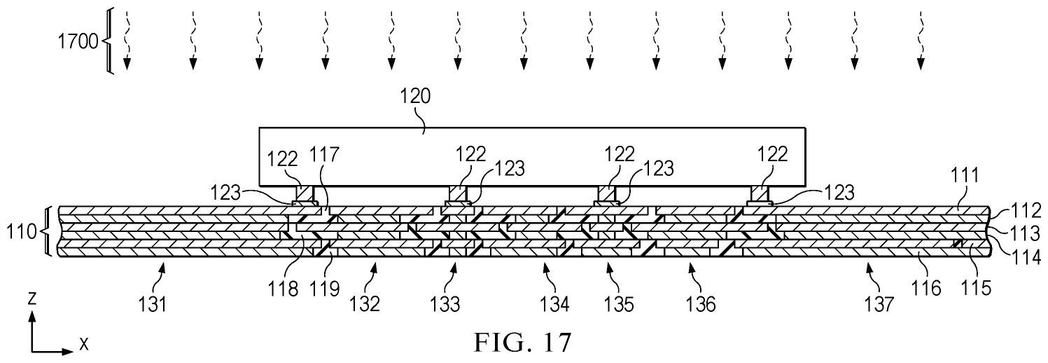

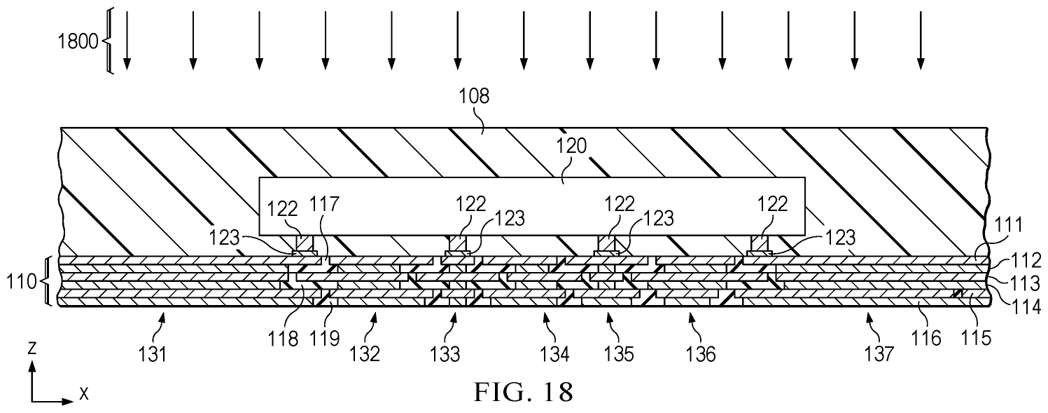

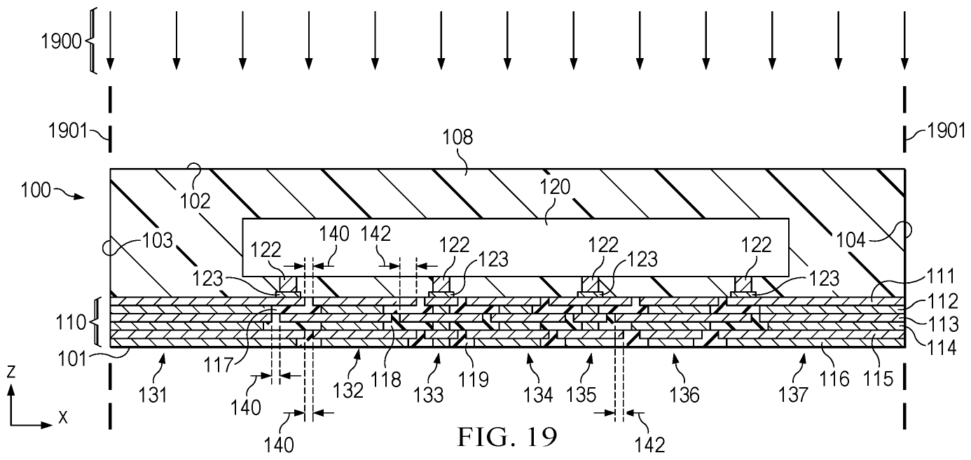

Referring now to FIGS. 2-19, FIG. 2 shows a method 200 of making an electronic device, FIGS. 3-15 show partial sectional side elevation views illustrating fabrication of the multilayer package substrate 110 for the electronic device 100 of FIGS. 1 and 1A, FIG. 16 shows a partial sectional side elevation view of die attach processing in fabrication of the electronic device 100, FIG. 17 shows a partial sectional side elevation view of solder reflow processing in fabrication of the electronic device 100, FIG. 18 shows a partial sectional side elevation view of mold processing in fabrication of the electronic device 100, and FIG. 19 shows a partial sectional side elevation view of package separation processing in fabrication of the electronic device 100 according to the example method 200.

The method 200 begins at 202 in FIG. 2 with fabricating or otherwise providing a multilevel package substrate. FIGS. 3-15 show one example, in which an electroplating steps are used to form patterned metal trace features and patterned metal via features, followed by compression molding of insulator material and planarization for each level of the multilevel package substrate 110 of FIGS. 1 and 1A described above. The multilevel package substrate 110 provided and/or manufactured at 202 in FIG. 2 includes the above-described features with multiple trace and via levels having metal stacks in two or more levels and adjacent (e.g., neighboring) metal stacks having overlapping metal traces. In one implementation, the multilevel package substrate 110 is fabricated in a separate fabrication process and is provided as an input component (e.g., a panel or strip with rows and columns of unit areas) to a different manufacturing process for packaging along with the semiconductor die 120. In another limitation, a single fabrication process creates the multilevel package substrate 110 and includes further processing to manufacture packaged semiconductor devices such as the electronic device 100.

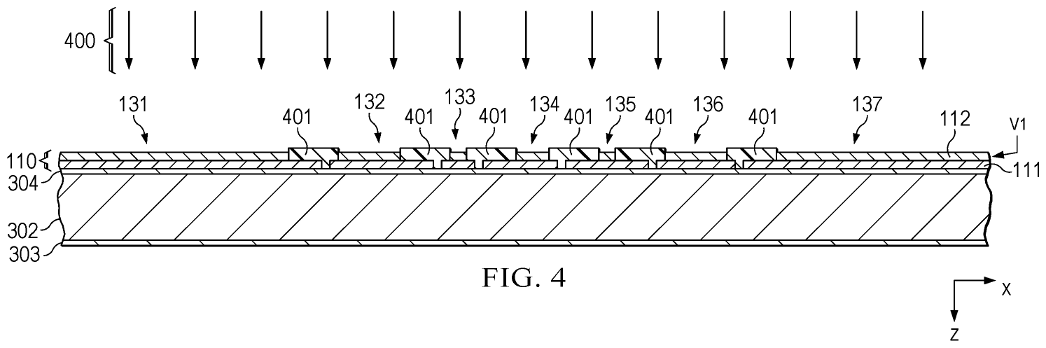

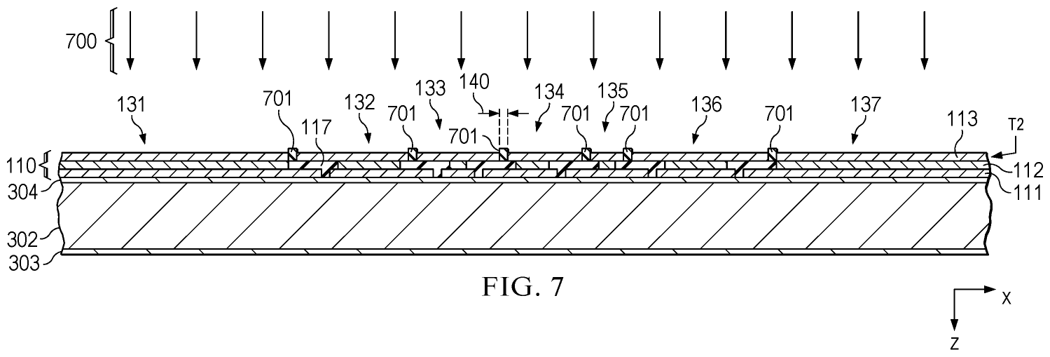

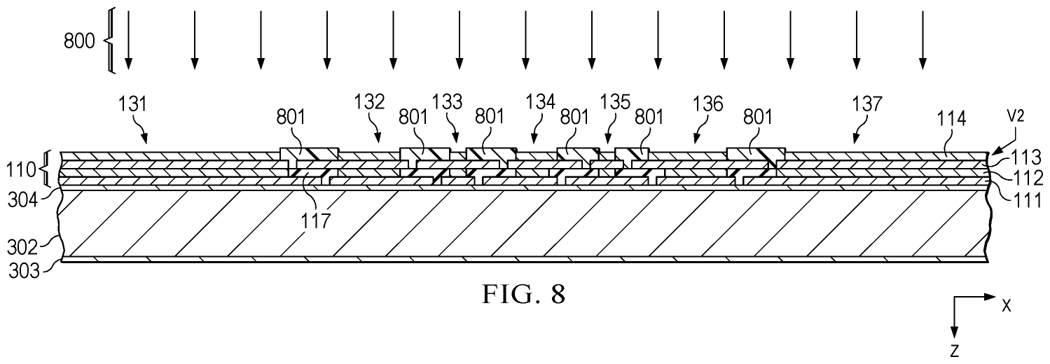

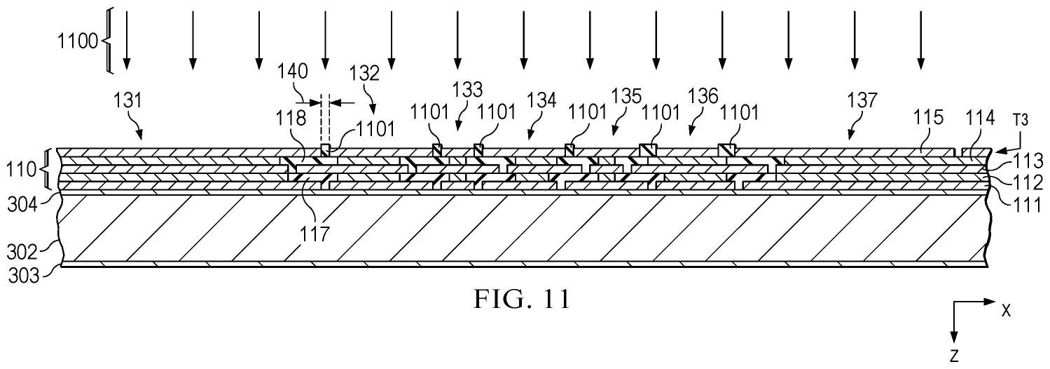

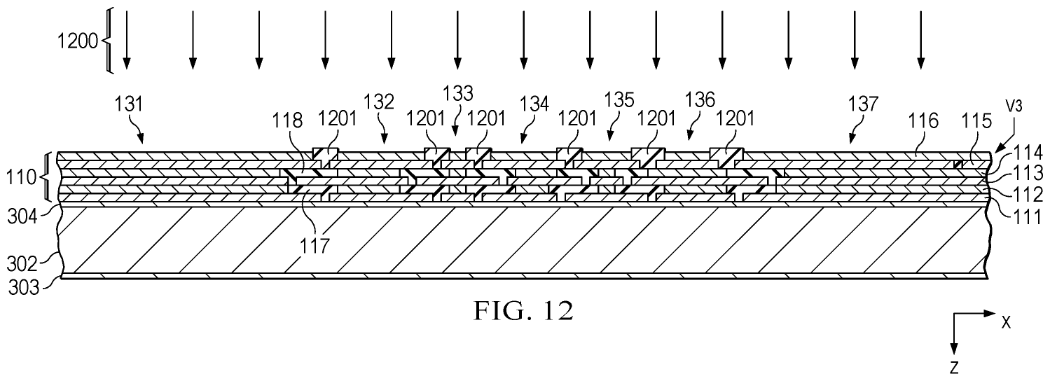

In the illustrated multilevel examples, the multilevel transformer substrate fabrication at 202 includes forming a first level (e.g., T1, V1 in FIGS. 3 and 4 below) on a carrier structure 302 in FIGS. 3 and 4, and subsequently forming a second level (e.g., T2, V2 in FIGS. 7 and 8) on the first level, as well as forming a third level (e.g., T3, V3 in FIGS. 11 and 12) on the second level, after which the carrier structure is removed from the first level. Following the fabrication of multiple rows and columns of the transformer substrate panel array, individual transformer substrates are separated from the panel structure and used as components in the fabrication of a panel or array of the electronic devices 100.

FIGS. 3-6 show formation of the first level of the multilevel package substrate 110 in one example, using an electroplating process 300 and a patterned plating mask 301. The illustrated example forms the first level having the patterned first traces 111, patterned first vias 112, and first molded insulator features 117. The first level formation starts with forming a first trace layer T1 that includes the patterned traces 111 using a stainless-steel carrier 302, such as a panel or strip with multiple prospective multilevel package substrate sections or unit areas, one of which is shown in FIG. 3. The illustrated example includes conductive metal features formed by electroplating which are or include copper. In other implementations, a different conductive metal can be used, such as aluminum or metals that include aluminum, etc. The carrier structure 302 in one example includes thin copper seed layers 303 and 304 formed by a blanket deposition process (not shown) such as chemical vapor deposition (CVD) on the respective bottom and top sides of the carrier structure 302 to facilitate subsequent electroplating via the process 300. The electroplating process 300 deposits copper onto the upper copper seed layer 304 in the portions of the topside of the carrier structure that are exposed through the patterned plating mask 301 to form the first patterned conductive features that form metal traces 111 in the first level of the multilevel package substrate 110, and the metal traces 111 in the first level are spaced apart by the spacing distance 140.

FIG. 4 shows the multilevel first package substrate 110 after the process 300 is completed and the plating mask 301 has been removed during formation of a first via layer V1 with the patterned vias 112 of the first level. A second electroplating process 400 is performed in FIG. 4 using a patterned second plating mask 401. The electroplating process 400 deposits further copper onto exposed portions of the first traces 111 to form the vias. After the electroplating process 400 is completed, the second plating mask 401 is removed.

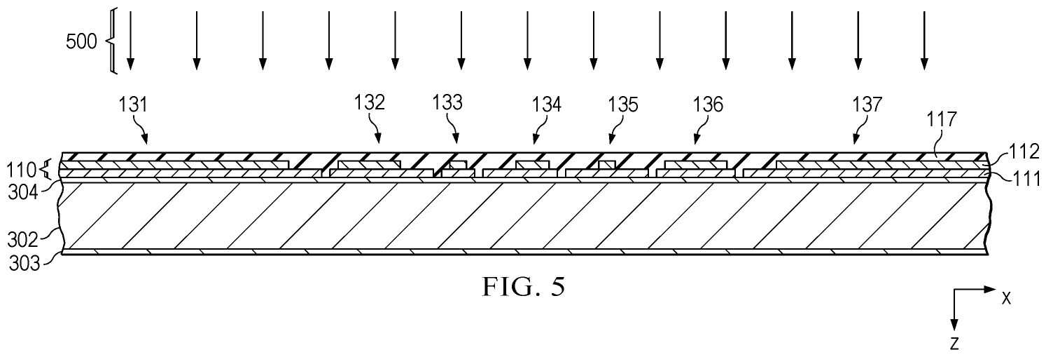

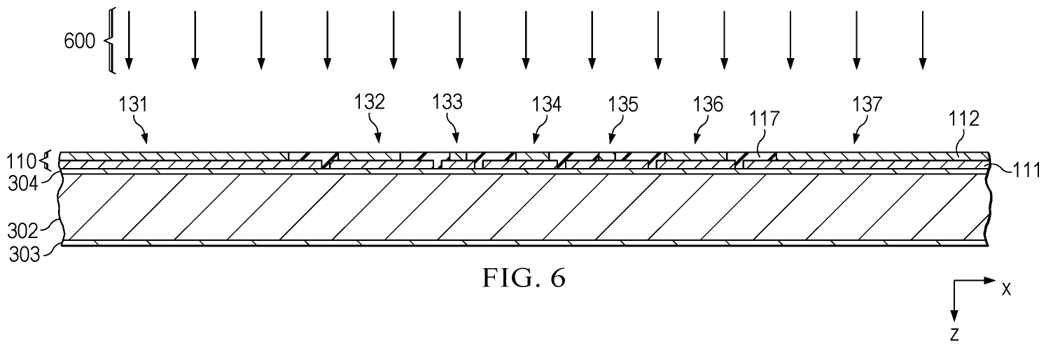

FIGS. 5 and 6 show formation of the first molded insulator features 117 in the first level of the multilevel package substrate 110. A compression molding process 500 is performed in FIG. 5 to form molded insulator features 117 on exposed portions of the metal features 111 of the first traces 111 and the copper metal vias 112 of the first level. The compression molding process 500 forms the insulator material 117 in FIG. 5 to an initial thickness that covers the first traces 111 and the first vias 112. A grinding process 600 is performed in FIG. 6, which grinds upper portions of the molded insulator material 117 and exposes the upper portions of the first vias 112. In another example, a chemical etch is used. In a further example, a chemical mechanical polishing (CMP) process is used. As shown in FIG. 6, the first molded insulator material 117 encloses a portion of the first traces 111.

FIGS. 7-10 show formation of the second level of the multilevel package substrate 110, including forming a second trace layer T2 with the patterned second metal traces 113, a second via layer V2 with the patterned second metal vias 114, and the second compression molded insulator material 118. In one example, the processing used to form the second level is similar to that used to form the first level, although not a requirement of all possible implementations. In the illustrated example, the second level processing forms the second level on the first level. FIG. 7 shows the multilevel package substrate 110 undergoing an electroplating process 700 with a patterned plating mask 701. The electroplating process 700 deposits copper onto the top side of the portions of the finished first level that are exposed through the plating mask 701 to form the second trace layer T2 including patterned conductive traces 113 of the second level. After the process 700 is completed, the plating mask 701 is removed. FIG. 8 shows the multilevel package substrate 110 undergoing another electroplating process 800 using another plating mask 801. The electroplating process 800 deposits further copper to form the second via level V2 including the second metal vias 114 in the areas exposed by the plating mask 801. After the process 800 is completed, the plating mask 801 is removed.

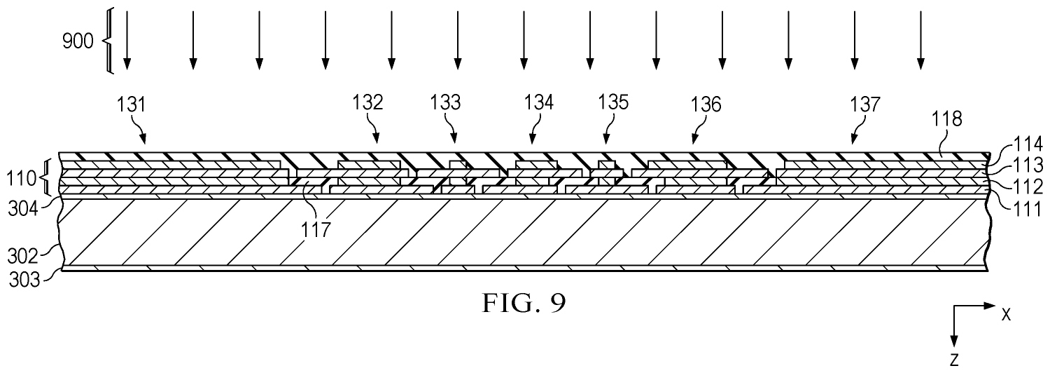

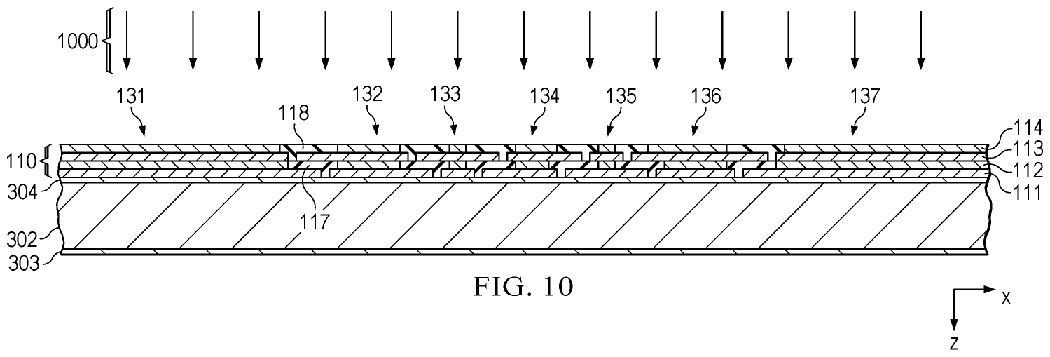

FIGS. 9 and 10 show formation of the second portions of the molded insulator features 118 in the second level using compression molding and grinding. A compression molding process 900 is performed in FIG. 9, which forms molded insulator features 118 on exposed portions of the conductive features of the second traces 113 and the second vias 114 of the second level to an initial thickness that covers the second traces 113 and the second vias 114. A grinding process 1000 is performed in FIG. 10, which grinds upper portions of the second portions of the molded insulator material 118 and exposes the upper portions of the second trace layer T2 and the second via layer V2. In another example, a chemical etch is used. In a further example, a chemical mechanical polishing process is used.

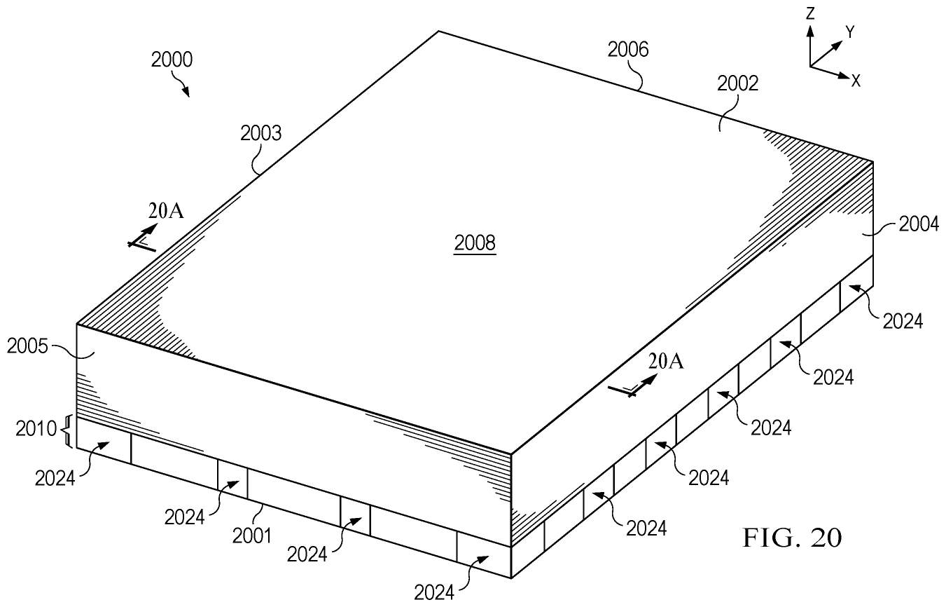

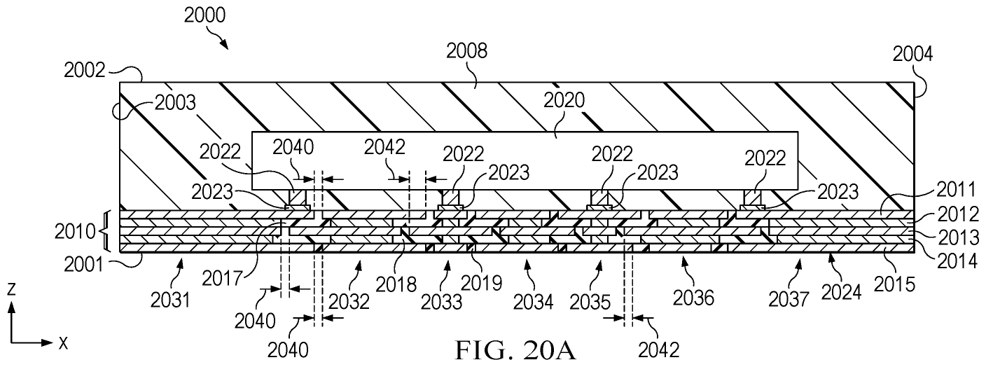

FIGS. 11-14 show formation of a third level of the multilevel package substrate 110, including forming a third trace layer T3 with the third traces 115, a third via layer V3 with the third vias 116, and third portions of the molded insulator features 119. In one example, the processing used to form the third level is similar to that used to form the first and second levels, although not a requirement of all possible implementations. In other implementations (e.g., FIGS. 20-22A below), one or more of the second via layer V2, the third trace layer T3, and the third via layer V3 can be omitted, for example, to provide a two level package substrate with or without vias in the second level, or a three-level package substrate with only two via layers.

In the illustrated example, the third level processing forms the third level on the second level. FIG. 11 shows the multilevel package substrate 110 undergoing another electroplating process 1100 with a patterned plating mask 1101. The electroplating process 1100 deposits copper onto the top side of the portions of the finished second level that are exposed through the patterned plating mask 1101 to form the third trace layer T3 including third patterned metal traces 115. After the process 1100 is completed, the plating mask 1101 is removed. FIG. 12 shows the multilevel package substrate 110 undergoing another electroplating process 1200 using another via plating mask 1201. The electroplating process 1200 deposits further copper to form the third via level V3 including the third vias 116 in the areas exposed by the via plating mask 1201. After the electroplating process 1200, the via plating mask 1201 is removed.

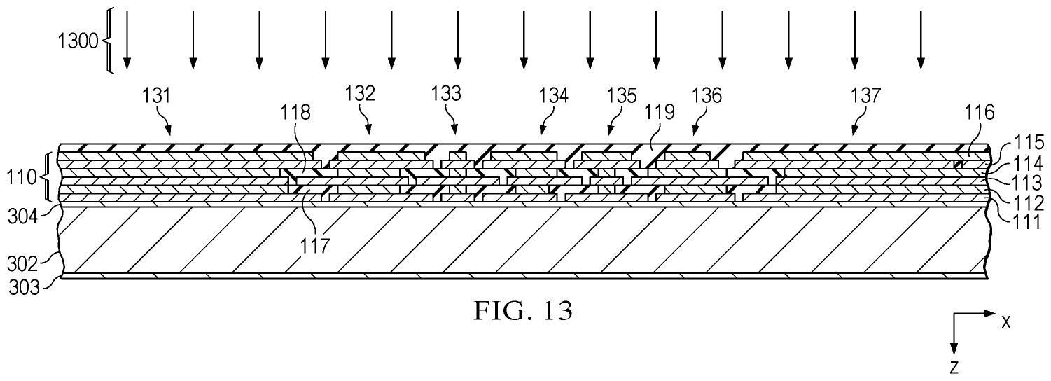

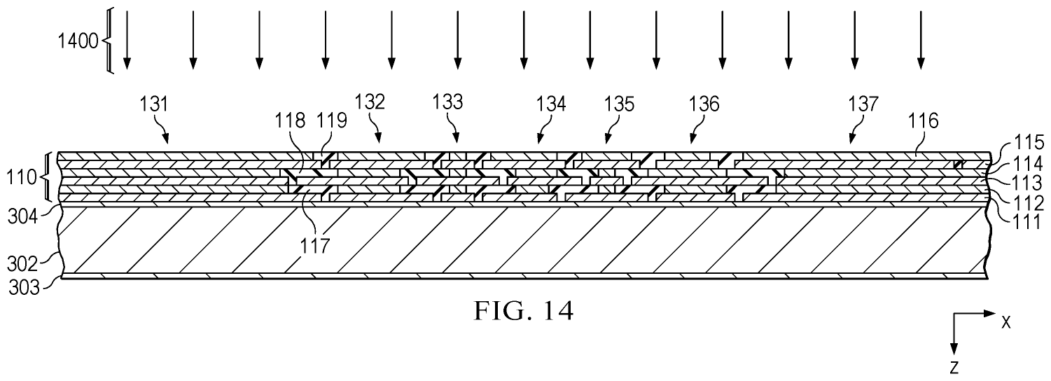

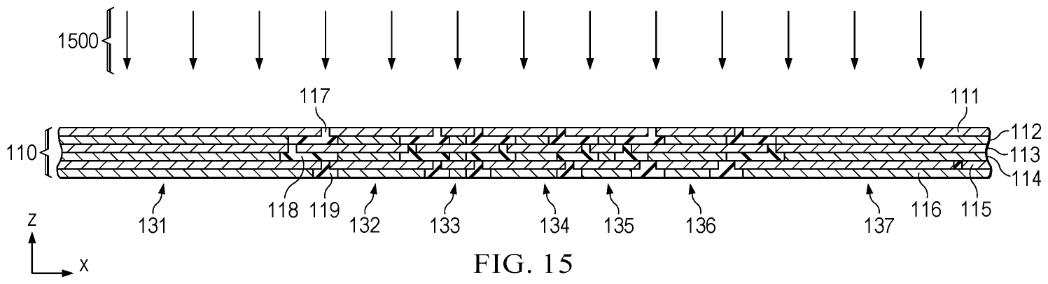

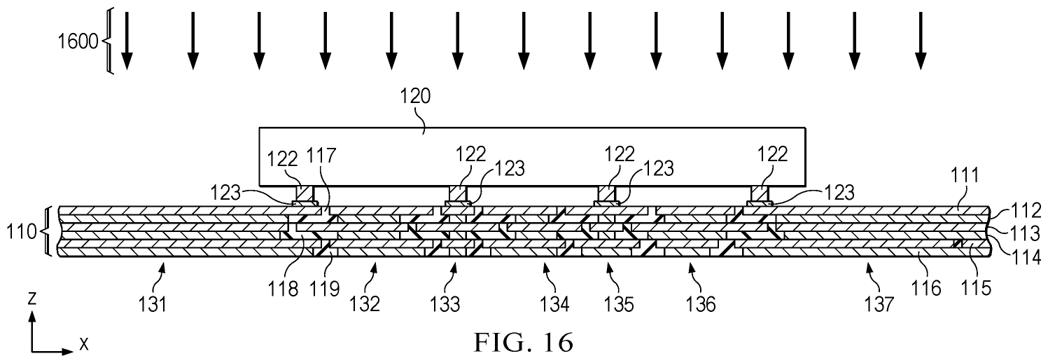

FIGS. 13 and 14 show the formation of the third molded insulator features 119 in the third level using compression molding and grinding. A compression molding process 1300 is performed in FIG. 13, which forms further molded insulator material 119 on exposed portions of the conductive features of the third traces 115 and the third vias 116 to an initial thickness that covers the third trace layer and the third via layer. A grinding process 1400 is performed in FIG. 14, which grinds upper portions of the molded insulator material 119 and exposes the upper portions of the third vias 116. In another example, a chemical etch is used. In a further example, a chemical mechanical polishing process is used. A process 1500 is performed in FIG. 15 that removes the carrier 302 and the exposed top side of the first level is etched to remove any remaining portions of the copper seed layer 304.

Referring also to FIGS. 2 and 16-19, the method 200 continues at 204 and 206 in FIG. 2 with die attach an electrical connection processing. In the illustrated example, the semiconductor die 120 is flip chip soldered to respective traces 111 of the first level of the multilevel package substrate 110 at 204 and 206. In another implementation, die attach processing can be performed with suitable adhesives, and electrical connections can be made by bond wires (not shown). In these or other examples, further components (e.g., additional semiconductor dies, passive components, etc., not shown) can be attached and electrically connected at 204 and 206. FIG. 16 shows one example, in which a die attach process 1600 is performed that attaches the semiconductor die 120 to the multilevel package substrate 110, for example, using automated pick and place equipment (not shown). In one implementation, bottoms of the conductive features 122 (e.g., copper pillars) of the semiconductor die 120 are dipped in solder 123, and the semiconductor die 120 is positioned as shown in FIG. 16 with the copper pillars 122 and associated solder placed on respective patterned first traces 111 of the multilevel package substrate 110. A thermal reflow process 1700 is performed as shown in FIG. 17, which heats and reflows the solder 123 to form solder connections between the conductive copper pillars 122 of the semiconductor die 120 and the respective metal traces 111 of the multilevel package substrate 110.

The method 200 continues at 208 with molding. FIG. 18 shows one example, in which a molding process 1800 is performed that forms a molded plastic package structure 108 that encloses the semiconductor die 120 and the exposed top side of the multilevel package substrate 110. The method 200 in one example also includes package separation at 210 in FIG. 2. FIG. 19 shows one example, in which a package separation process 1900 is performed that separates individual packaged electronic devices 100 from a panel array, for example, using saw or laser cutting. As shown in FIG. 19, the separation process 1900 in one example includes cutting along lines 1901 that are parallel to the second direction Y (e.g., into the page) to form the device sides 103 and 104, and similar cutting operations are used along cut lines parallel to the first direction X to form the front and back sides 105 and 106 (not shown in FIG. 19). The resulting packaged electronic device 100 is shown in FIGS. 1 and 1A discussed above.

Another example electronic device 2000 is illustrated in FIGS. 20 and 20A, where FIG. 20 shows a top perspective view and FIG. 20A shows a sectional side elevation view of the electronic device 2000 taken along line 20A-20A of FIG. 20. FIGS. 20 and 20A show top perspective and sectional side views of a packaged electronic device 2000 with a multilevel package substrate 2010 having interleaved overlapping traces of adjacent metal stacks to mitigate cracks and crack propagation and add structural strength reinforcement in the multilevel package substrate 2010. The electronic device 2000 in this example is similar to the electronic device 100 described above, except that the multilevel package substrate 2010 is a three level structure that does not include third vias, and the bottom side 2001 of the electronic device 2000 exposes bottom sides of patterned third metal traces 2015 and portions of a third insulator material 2019.

The electronic device 2000 is shown in FIGS. 20 and 20A in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. The electronic device 2000 has a package structure 2008, such as a molded plastic, and the electronic device has opposite first and second (e.g., bottom and top) sides 2001 and 2002, respectively, which are spaced apart from one another along the third direction Z. The package structure 2008 and the electronic device 2000 have laterally opposite third and fourth sides 2003 and 2004 spaced apart from one another along the first direction X, and opposite fifth and sixth sides 2005 and 2006 spaced apart from one another along the second direction Y in the illustrated orientation. The sides 2001-2006 in one example have substantially planar outer surfaces. In other examples, one or more of the sides 2001-2006 have curves, angled features, or other non-planar surface features.

As best shown in FIG. 20A, the multilevel package substrate 2010 has three levels in a stacked arrangement along the third direction Z. In this example, the individual levels have conductive metal features that form upper patterned traces and lower vias, as well as electrical insulator material that extends between and around the conductive metal features. In one example, the conductive metal features of the individual levels are or include copper. In another example, the conductive metal features are or include aluminum or other suitable electrically conductive metal material. In the illustrated example, the upper or first level includes patterned metal traces 2011, metal vias 2012, and compression molded insulator material 2017 that extends between and around the traces 2011 and the vias 2012. A middle or second level includes patterned metal traces 2013, metal vias 2014, and compression molded insulator material 2018 that extends between and around the traces 2013 and the vias 2014. The first level 2011, 2012, 2017 extends in a first plane of the respective first and second directions X and Y and the second level 2013, 2014, 2018 extends in a second plane of the first and second directions X and Y, and the first and second planes are spaced apart from one another along the third direction Z. In this example, a bottom or third level includes patterned metal traces 2015 and compression molded insulator material 2019 that extends between and around the traces 2015, and the third level 2015, 2016, 2019 extends in a third plane of the first and second directions X and Y.

The electronic device 2000 includes a semiconductor die 2020 (FIG. 20A) mounted to the top side of the first level of the multilevel package substrate 2010. The semiconductor die 2020 includes conductive metal features 2022 that operate as terminals for electrical connection of circuitry within the semiconductor die 2020 and traces of the multilevel package substrate 2010. In one example, the conductive features 2022 are copper or other conductive metal formed as bond pads suitable for bond wire connection in the electronic device 2000. In the illustrated example, the conductive features 2022 are copper pillars and the semiconductor die 2020 is flip chip attached to the top side of the first level of the multilevel package substrate 2010, with the conductive features 2022 soldered to the top sides of select metal traces 2011 by solder 2023 to provide electrical connection of the semiconductor die 2020 to conductive features of the multilevel package substrate 2010.

As further shown in FIG. 20, the multilevel package substrate 2010 includes conductive features that form or operate as leads 2024 suitable for soldering to a host printed circuit board (PCB, not shown). The multilevel package substrate 2010 provides interconnection routing between an electronic component or components of the semiconductor die 2020 and the leads 2024. In certain implementations, moreover, the electronic device 2000 can include further electronic components (not shown), such as one or more additional semiconductor dies, passive circuit components (e.g., resistors, capacitors, inductors, etc.) to form one or more circuits with suitable electrical connections to one or more of the leads 2024. The illustrated electronic device 2000 is a quad flat no-lead (QFN) type packaged electronic device having leads 2024 with exposed bottom sides along the first side 2001 of the electronic device 2000, and exposed conductive sidewalls. Different lead types and package types can be used in different implementations, including leads that extend outward from one or more lateral sides 2003-2006 (e.g., gullwing leads, J leads, etc.), as well as ball grid array (BGA) terminals disposed along the bottom or first side 2001 of the electronic device 2000 to facilitate soldering to a host PCB.

The leads 2024 and other conductive features of the multilevel package substrate 2010 form metal stacks that include contiguous metal structures of two or more of the levels of the multilevel package substrate 2010. The electronic device 2000 can have any number of metal stacks in the multilevel package substrate 2010. FIG. 20A illustrates example metal stacks 2031, 2032, 2033, 2034, 2035, 2036 and 2037. In this example, each of the illustrated metal stacks 2031-2037 include a corresponding set of contiguous metal structures of all three levels. In other examples, one or more of the metal stacks include contiguous metal structures of fewer than all the levels of the multilevel package substrate 2010. In the illustrated example, the first and seventh metal stacks 2031 and 2037 extend along the respective third and fourth sides 2003 and 2004 and form corresponding ones of the leads 2024 of the electronic device 2000.

The multilevel package substrate 2010 advantageously provides interleaved overlapping traces in one or more pairs of adjacent or neighboring metal stacks. The overlap of metal traces in certain implementations helps to mitigate crack formation and/or crack propagation in the insulator material 2017, 2018, and/or 2019 of the multilevel package substrate 2010. The adjacent or neighboring metal stacks are spaced apart from one another, and may, but need not be, electrically connected to one another in the multilevel package substrate 2010 As shown in FIG. 20A, for example, the respective first and second metal stacks 2031 and 2032 are spaced apart from one another along the first direction X and are not electrically connected to one another. In one implementation, the metal stacks 2031-2037 are spaced apart from one another in both the first and second directions X and Y, respectively. The first metal stack 2031 in this example includes a first set of contiguous metal structures formed by patterned metal of the metal traces 2011, 2013, and 2015 and the vias 2012 and 2014. In the illustrated example, the second metal stack 2032 includes a second set of contiguous metal structures formed by the patterned metal of the metal traces 2011, 2013, and 2015 and the vias 2012 and 2014. The other illustrated metal stacks 2033-2037 in this example include corresponding sets of contiguous metal structures formed by patterned metal of the metal traces 2011, 2013, and 2015 and the vias 2012 and 2014. In other implementations, one or more of the metal stacks can include sets of contiguous metal structures formed by patterned metal of fewer than all of the metal traces and/or vias.

In the illustrated example, a first metal trace 2011 of the first metal stack in the first level of the multilevel package substrate 2010 partially overlaps a second metal trace 2013 of the second metal stack 2032 in the second level of the multilevel package substrate 2010. In this example, a metal trace 2015 of the first metal stack and the third level of the multilevel package substrate 2010 partially overlaps the second metal trace 2013 of the second metal stack 2032 and the second level. Similar metal trace partial overlap is seen in the other adjacent or neighboring pairs of metal stacks 2031-2037 in the example of FIG. 20A. Although the illustrated sectional line along line 20A-20A of FIGS. 20 and 20A illustrates a partial overlapping of metal traces in different levels in adjacent metal stacks 2031-2037 along the first direction X, similar features are provided along the second direction Y and other directions in a plane of the first and second directions X and Y, respectively.

The example electronic device 2000 of FIGS. 20 and 20A also incorporates controlled spacing of trace and via features within the individual levels, in which the metal structures of the metal stacks 2031-2037 are spaced apart from one another by a non-zero spacing distance 2040. For example, the metal traces of the first and second metal stacks 2031 and 2032 are spaced apart from one another in the respective first and second planes by a spacing distance 2040. In one or more implementations, the metal structures of the neighboring or adjacent metal stacks are spaced apart from one another by a spacing distance 2040 that is greater than or equal to 30 μm and less than 50 μm. Manufacturing limitations regarding feature size and spacing can allow spacing distances 2040 of less than 30 μm in certain implementations, for example, down to 20 μm or even 15 μm in certain examples. Increasing the spacing distances 2040 beyond about 50 μm is possible in these or other examples, but excessive spacing distances 2040 can increase the possibility of cracks and/or crack propagation. In the illustrated example, several examples of trace spacing distances 2040 are indicated in FIG. 20A, and larger capital X-Y plane spacing distances between metal via features of the multilevel package substrate 2010 may result from the fabrication processing technology used in making the multilevel package substrate 2010, for example, in which via structures of a given level are generally narrower than the corresponding trace features of the given level.

In addition, the overlapping metal traces of the adjacent or neighboring metal stacks 2031-2037 overlap one another by a non-zero overlap distance 2042. In one implementation, the overlap distance 2042 is greater than the spacing distance 2040. In this or another example, the overlap distance 2042 is greater than or equal to 25 μm. Overlap distances 2042 less than 25 μm can be used but may increase the linearity of crack propagation paths through the insulator material 2017-2019 of the multilevel package substrate 2010. Increasing the overlap distances 2042 can help mitigate or prevent cracks and/or crack propagation in the insulator material 2017-2019, but practical limits to the overlap distances 2042 may arise in specific designs, for example, due to limited X-Y plane spacing requirements for the overall dimensions of the electronic device 2000.

As further shown in FIGS. 20 and 20A, the molded package structure 2008 encloses the semiconductor die 2020 and an upper portion of the multilevel package substrate 2010. In other implementations, the molded package structure 2008 can enclose further portions of the multilevel package substrate 2010, for example, along one or more of the lateral sides 2003-2006. The illustrated example allows solder wicking along exposed side portions of the leads 2024, for example, in QFN or other package types and applications, to facilitate optical inspection of solder joints, etc.

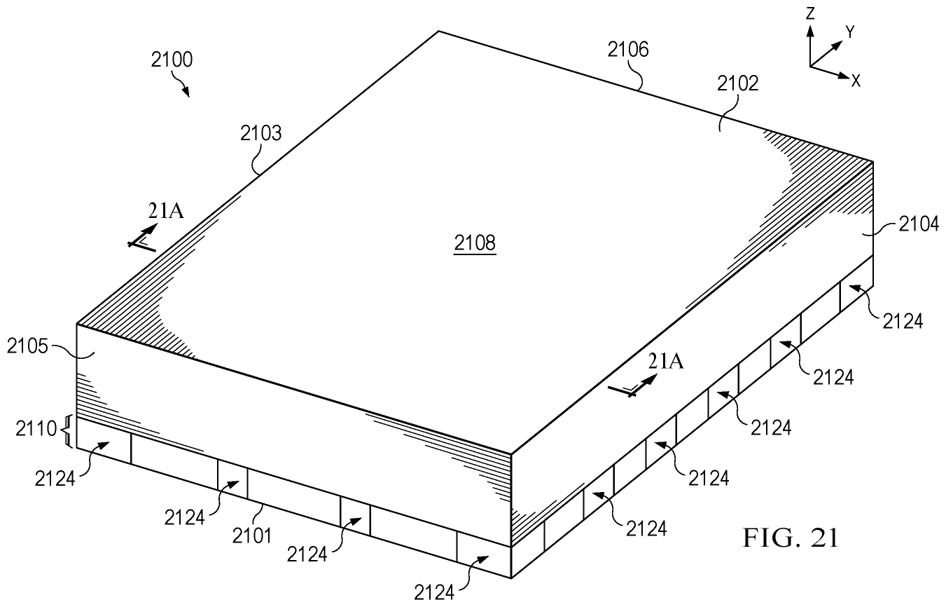

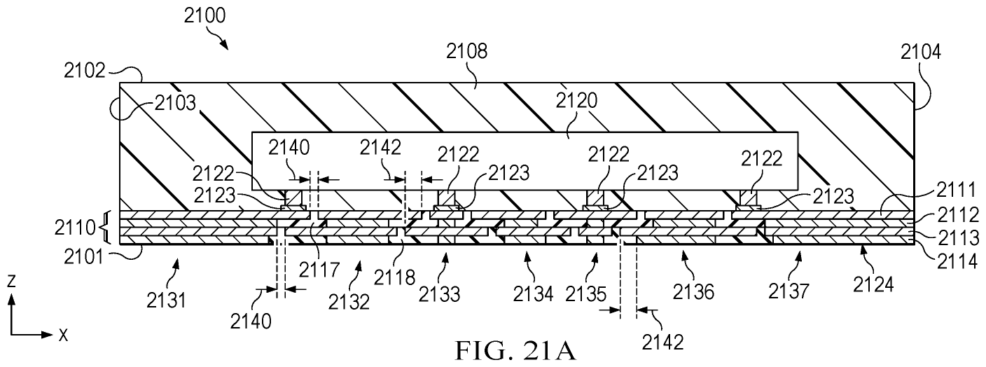

Another example electronic device 2100 is illustrated in FIGS. 21 and 21A, where FIG. 21 shows a top perspective view and FIG. 21A shows a sectional side elevation view of the electronic device 2100 taken along line 21A-21A of FIG. 21. FIGS. 21 and 21A show top perspective and sectional side views of a packaged electronic device 2100 with a multilevel package substrate 2110 having interleaved overlapping traces of adjacent metal stacks to mitigate cracks and crack propagation and add structural strength reinforcement in the multilevel package substrate 2110. The electronic device 2100 in this example is similar to the electronic device 100 described above, except that the multilevel package substrate 2110 is a two level structure and the bottom side 2101 of the electronic device 2100 exposes bottom sides of patterned second vias 2114 and portions of a second insulator material 2118.

The electronic device 2100 is shown in FIGS. 21 and 21A in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. The electronic device 2100 has a package structure 2108, such as a molded plastic, and the electronic device has opposite first and second (e.g., bottom and top) sides 2101 and 2102, respectively, which are spaced apart from one another along the third direction Z. The package structure 2108 and the electronic device 2100 have laterally opposite third and fourth sides 2103 and 2104 spaced apart from one another along the first direction X, and opposite fifth and sixth sides 2105 and 2106 spaced apart from one another along the second direction Y in the illustrated orientation. The sides 2101-2106 in one example have substantially planar outer surfaces. In other examples, one or more of the sides 2101-2106 have curves, angled features, or other non-planar surface features.

As best shown in FIG. 21A, the multilevel package substrate 2110 has two levels in a stacked arrangement along the third direction Z. In this example, the individual levels have conductive metal features that form upper patterned traces and lower vias, as well as electrical insulator material or features that extends between and around the conductive metal features. In one example, the conductive metal features of the individual levels are or include copper. In another example, the conductive metal features are or include aluminum or other suitable electrically conductive metal material. In the illustrated example, the upper or first level includes patterned metal traces 2111, metal vias 2112, and compression molded insulator material 2117 that extends between and around the traces 2111 and the vias 2112. A bottom or second level includes patterned metal traces 2113, metal vias 2114, and compression molded insulator material 2118 that extends between and around the traces 2113 and the vias 2114. The first level 2111, 2112, 2117 extends in a first plane of the respective first and second directions X and Y and the second level 2113, 2114, 2118 extends in a second plane of the first and second directions X and Y, and the first and second planes are spaced apart from one another along the third direction Z.

The electronic device 2100 includes a semiconductor die 2120 (FIG. 21A) mounted to the top side of the first level of the multilevel package substrate 2110. The semiconductor die 2120 includes conductive metal features 2122 that operate as terminals for electrical connection of circuitry within the semiconductor die 2120 and traces of the multilevel package substrate 2110. In one example, the conductive features 2122 are copper or other conductive metal formed as bond pads suitable for bond wire connection in the electronic device 2100. In the illustrated example, the conductive features 2122 are copper pillars and the semiconductor die 2120 is flip chip attached to the top side of the first level of the multilevel package substrate 2110, with the conductive features 2122 soldered to the top sides of select metal traces 2111 by solder 2123 to provide electrical connection of the semiconductor die 2120 to conductive features of the multilevel package substrate 2110.

As further shown in FIG. 21, the multilevel package substrate 2110 includes conductive features that form or operate as leads 2124 suitable for soldering to a host printed circuit board (PCB, not shown). The multilevel package substrate 2110 provides interconnection routing between an electronic component or components of the semiconductor die 2120 and the leads 2124. In certain implementations, moreover, the electronic device 2100 can include further electronic components (not shown), such as one or more additional semiconductor dies, passive circuit components (e.g., resistors, capacitors, inductors, etc.) to form one or more circuits with suitable electrical connections to one or more of the leads 2124. The illustrated electronic device 2100 is a quad flat no-lead (QFN) type packaged electronic device having leads 2124 with exposed bottom sides along the first side 2101 of the electronic device 2100, and exposed conductive sidewalls. Different lead types and package types can be used in different implementations, including leads that extend outward from one or more lateral sides 2103-2106 (e.g., gullwing leads, J leads, etc.), as well as ball grid array (BGA) terminals disposed along the bottom or first side 2101 of the electronic device 2100 to facilitate soldering to a host PCB.

The leads 2124 and other conductive features of the multilevel package substrate 2110 form metal stacks that include contiguous metal structures of two of the levels of the multilevel package substrate 2110. The electronic device 2100 can have any number of metal stacks in the multilevel package substrate 2110. FIG. 21A illustrates example metal stacks 2131, 2132, 2133, 2134, 2135, 2136 and 2137. In this example, each of the illustrated metal stacks 2131-2137 include a corresponding set of contiguous metal structures of both levels. In other examples, one or more of the metal stacks include contiguous metal structures of fewer than all the levels of the multilevel package substrate 2110. In the illustrated example, the first and seventh metal stacks 2131 and 2137 extend along the respective third and fourth sides 2103 and 2104 and form corresponding ones of the leads 2124 of the electronic device 2100.

The multilevel package substrate 2110 advantageously provides interleaved overlapping traces in one or more pairs of adjacent or neighboring metal stacks. The overlap of metal traces in certain implementations helps to mitigate crack formation and/or crack propagation in the insulator material 2117 and/or 2118 of the multilevel package substrate 2110. The adjacent or neighboring metal stacks are spaced apart from one another, and may, but need not be, electrically connected to one another in the multilevel package substrate 2110 As shown in FIG. 21A, for example, the respective first and second metal stacks 2131 and 2132 are spaced apart from one another along the first direction X and are not electrically connected to one another. In one implementation, the metal stacks 2131-2137 are spaced apart from one another in both the first and second directions X and Y, respectively. The first metal stack 2131 in this example includes a first set of contiguous metal structures formed by patterned metal of the metal traces 2111 and 2113, and the vias 2112 and 2114. In the illustrated example, the second metal stack 2132 includes a second set of contiguous metal structures formed by the patterned metal of the metal traces 2111 and 2113 and the vias 2112 and 2114. The other illustrated metal stacks 2133-2137 in this example include corresponding sets of contiguous metal structures formed by patterned metal of the metal traces 2111 and 2113, and the vias 2112 and 2114. In other implementations, one or more of the metal stacks can include sets of contiguous metal structures formed by patterned metal of fewer than all of the metal traces and/or vias.

In the illustrated example, a first metal trace 2111 of the first metal stack in the first level of the multilevel package substrate 2110 partially overlaps a second metal trace 2113 of the second metal stack 2132 in the second level of the multilevel package substrate 2110. Similar metal trace partial overlap is seen in the other adjacent or neighboring pairs of metal stacks 2131-2137 in the example of FIG. 21A. Although the illustrated sectional line along line 21A-21A of FIGS. 21 and 21A illustrates a partial overlapping of metal traces in different levels in adjacent metal stacks 2131-2137 along the first direction X, similar features are provided along the second direction Y and other directions in a plane of the first and second directions X and Y, respectively.

The example electronic device 2100 of FIGS. 21 and 21A also incorporates controlled spacing of trace and via features within the individual levels, in which the metal structures of the metal stacks 2131-2137 are spaced apart from one another by a non-zero spacing distance 2140. For example, the metal traces of the first and second metal stacks 2131 and 2132 are spaced apart from one another in the respective first and second planes by a spacing distance 2140. In one or more implementations, the metal structures of the neighboring or adjacent metal stacks are spaced apart from one another by a spacing distance 2140 that is greater than or equal to 30 μm and less than 50 μm. Manufacturing limitations regarding feature size and spacing can allow spacing distances 2140 of less than 30 μm in certain implementations, for example, down to 20 μm or even 15 μm in certain examples. Increasing the spacing distances 2140 beyond about 50 μm is possible in these or other examples, but excessive spacing distances 2140 can increase the possibility of cracks and/or crack propagation. In the illustrated example, several examples of trace spacing distances 2140 are indicated in FIG. 21A, and larger capital X-Y plane spacing distances between metal via features of the multilevel package substrate 2110 may result from the fabrication processing technology used in making the multilevel package substrate 2110, for example, in which via structures of a given level are generally narrower than the corresponding trace features of the given level.

In addition, the overlapping metal traces of the adjacent or neighboring metal stacks 2131-2137 overlap one another by a non-zero overlap distance 2142. In one implementation, the overlap distance 2142 is greater than the spacing distance 2140. In this or another example, the overlap distance 2142 is greater than or equal to 25 μm. Overlap distances 2142 less than 25 μm can be used but may increase the linearity of crack propagation paths through the insulator material 2117-2119 of the multilevel package substrate 2110. Increasing the overlap distances 2142 can help mitigate or prevent cracks and/or crack propagation in the insulator material 2117-2119, but practical limits to the overlap distances 2142 may arise in specific designs, for example, due to limited X-Y plane spacing requirements for the overall dimensions of the electronic device 2100.

As further shown in FIGS. 21 and 21A, the molded package structure 2108 encloses the semiconductor die 2120 and an upper portion of the multilevel package substrate 2110. In other implementations, the molded package structure 2108 can enclose further portions of the multilevel package substrate 2110, for example, along one or more of the lateral sides 2103-2106. The illustrated example allows solder wicking along exposed side portions of the leads 2124, for example, in QFN or other package types and applications, to facilitate optical inspection of solder joints, etc.

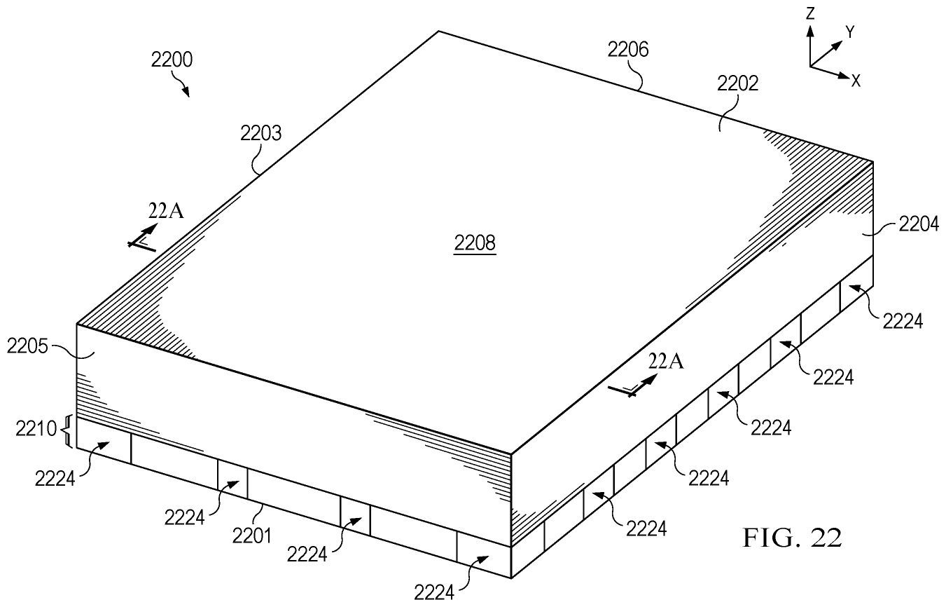

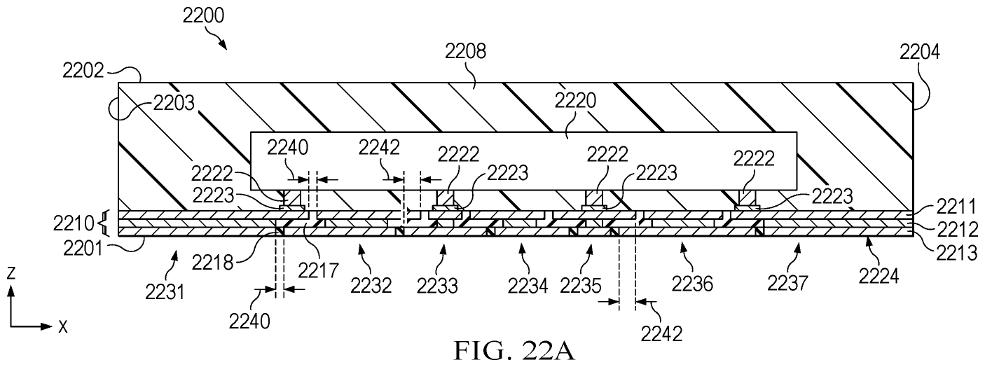

FIGS. 22 and 22A show another example electronic device 2200, in which FIG. 22 shows a top perspective view and FIG. 22A shows a sectional side elevation view of the electronic device 2200 taken along line 22A-22A of FIG. 22. FIGS. 22 and 22A show top perspective and sectional side views of a packaged electronic device 2200 with a multilevel package substrate 2210 having interleaved overlapping traces of adjacent metal stacks to mitigate cracks and crack propagation and add structural strength reinforcement in the multilevel package substrate 2210. The electronic device 2200 in this example is similar to the electronic device 100 described above, except that the multilevel package substrate 2210 is a two level structure and the bottom side 2201 of the electronic device 2200 exposes bottom sides of patterned second traces 2213 and portions of a second insulator material 2218.

The electronic device 2200 is shown in FIGS. 22 and 22A in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. The electronic device 2200 has a package structure 2208, such as a molded plastic, and the electronic device has opposite first and second (e.g., bottom and top) sides 2201 and 2202, respectively, which are spaced apart from one another along the third direction Z. The package structure 2208 and the electronic device 2200 have laterally opposite third and fourth sides 2203 and 2204 spaced apart from one another along the first direction X, and opposite fifth and sixth sides 2205 and 2206 spaced apart from one another along the second direction Y in the illustrated orientation. The sides 2201-2206 in one example have substantially planar outer surfaces. In other examples, one or more of the sides 2201-2206 have curves, angled features, or other non-planar surface features.

As best shown in FIG. 22A, the multilevel package substrate 2210 has two levels in a stacked arrangement along the third direction Z. In this example, the individual levels have conductive metal features that form upper patterned traces and lower vias, as well as electrical insulator material or features that extends between and around the conductive metal features. In one example, the conductive metal features of the individual levels are or include copper. In another example, the conductive metal features are or include aluminum or other suitable electrically conductive metal material. In the illustrated example, the upper or first level includes patterned metal traces 2211, metal vias 2212, and compression molded insulator material 2217 that extends between and around the traces 2211 and the vias 2212. A bottom or second level includes patterned metal traces 2213 and compression molded insulator material 2218 that extends between and around the traces 2213. The first level 2211, 2212, 2217 extends in a first plane of the respective first and second directions X and Y and the second level 2213, 2218 extends in a second plane of the first and second directions X and Y, and the first and second planes are spaced apart from one another along the third direction Z.

The electronic device 2200 includes a semiconductor die 2220 (FIG. 22A) mounted to the top side of the first level of the multilevel package substrate 2210. The semiconductor die 2220 includes conductive metal features 2222 that operate as terminals for electrical connection of circuitry within the semiconductor die 2220 and traces of the multilevel package substrate 2210. In one example, the conductive features 2222 are copper or other conductive metal formed as bond pads suitable for bond wire connection in the electronic device 2200. In the illustrated example, the conductive features 2222 are copper pillars and the semiconductor die 2220 is flip chip attached to the top side of the first level of the multilevel package substrate 2210, with the conductive features 2222 soldered to the top sides of select metal traces 2211 by solder 2223 to provide electrical connection of the semiconductor die 2220 to conductive features of the multilevel package substrate 2210.

As further shown in FIG. 22, the multilevel package substrate 2210 includes conductive features that form or operate as leads 2224 suitable for soldering to a host printed circuit board (PCB, not shown). The multilevel package substrate 2210 provides interconnection routing between an electronic component or components of the semiconductor die 2220 and the leads 2224. In certain implementations, moreover, the electronic device 2200 can include further electronic components (not shown), such as one or more additional semiconductor dies, passive circuit components (e.g., resistors, capacitors, inductors, etc.) to form one or more circuits with suitable electrical connections to one or more of the leads 2224. The illustrated electronic device 2200 is a quad flat no-lead (QFN) type packaged electronic device having leads 2224 with exposed bottom sides along the first side 2201 of the electronic device 2200, and exposed conductive sidewalls. Different lead types and package types can be used in different implementations, including leads that extend outward from one or more lateral sides 2203-2206 (e.g., gullwing leads, J leads, etc.), as well as ball grid array (BGA) terminals disposed along the bottom or first side 2201 of the electronic device 2200 to facilitate soldering to a host PCB.

The leads 2224 and other conductive features of the multilevel package substrate 2210 form metal stacks that include contiguous metal structures of two of the levels of the multilevel package substrate 2210. The electronic device 2200 can have any number of metal stacks in the multilevel package substrate 2210. FIG. 22A illustrates example metal stacks 2231, 2232, 2233, 2234, 2235, 2236 and 2237. In this example, each of the illustrated metal stacks 2231-2237 include a corresponding set of contiguous metal structures of both levels. In other examples, one or more of the metal stacks include contiguous metal structures of fewer than all the levels of the multilevel package substrate 2210. In the illustrated example, the first and seventh metal stacks 2231 and 2237 extend along the respective third and fourth sides 2203 and 2204 and form corresponding ones of the leads 2224 of the electronic device 2200.

The multilevel package substrate 2210 advantageously provides interleaved overlapping traces in one or more pairs of adjacent or neighboring metal stacks. The overlap of metal traces in certain implementations helps to mitigate crack formation and/or crack propagation in the insulator material 2217 and/or 2218 of the multilevel package substrate 2210. The adjacent or neighboring metal stacks are spaced apart from one another, and may, but need not be, electrically connected to one another in the multilevel package substrate 2210 As shown in FIG. 22A, for example, the respective first and second metal stacks 2231 and 2232 are spaced apart from one another along the first direction X and are not electrically connected to one another. In one implementation, the metal stacks 2231-2237 are spaced apart from one another in both the first and second directions X and Y, respectively. The first metal stack 2231 in this example includes a first set of contiguous metal structures formed by patterned metal of the metal traces 2211 and 2213, and the vias 2212. In the illustrated example, the second metal stack 2232 includes a second set of contiguous metal structures formed by the patterned metal of the metal traces 2211 and 2213 and the vias 2212. The other illustrated metal stacks 2233-2237 in this example include corresponding sets of contiguous metal structures formed by patterned metal of the metal traces 2211 and 2213, and the vias 2212. In other implementations, one or more of the metal stacks can include sets of contiguous metal structures formed by patterned metal of fewer than all of the metal traces and/or vias.

In the illustrated example, a first metal trace 2211 of the first metal stack in the first level of the multilevel package substrate 2210 partially overlaps a second metal trace 2213 of the second metal stack 2232 in the second level of the multilevel package substrate 2210. Similar metal trace partial overlap is seen in the other adjacent or neighboring pairs of metal stacks 2231-2237 in the example of FIG. 22A. Although the illustrated sectional line along line 22A-22A of FIGS. 22 and 22A illustrates a partial overlapping of metal traces in different levels in adjacent metal stacks 2231-2237 along the first direction X, similar features are provided along the second direction Y and other directions in a plane of the first and second directions X and Y, respectively.

The example electronic device 2200 of FIGS. 22 and 22A also incorporates controlled spacing of trace and via features within the individual levels, in which the metal structures of the metal stacks 2231-2237 are spaced apart from one another by a non-zero spacing distance 2240. For example, the metal traces of the first and second metal stacks 2231 and 2232 are spaced apart from one another in the respective first and second planes by a spacing distance 2240. In one or more implementations, the metal structures of the neighboring or adjacent metal stacks are spaced apart from one another by a spacing distance 2240 that is greater than or equal to 30 μm and less than 50 μm. Manufacturing limitations regarding feature size and spacing can allow spacing distances 2240 of less than 30 μm in certain implementations, for example, down to 20 μm or even 15 μm in certain examples. Increasing the spacing distances 2240 beyond about 50 μm is possible in these or other examples, but excessive spacing distances 2240 can increase the possibility of cracks and/or crack propagation. In the illustrated example, several examples of trace spacing distances 2240 are indicated in FIG. 22A, and larger capital X-Y plane spacing distances between metal via features of the multilevel package substrate 2210 may result from the fabrication processing technology used in making the multilevel package substrate 2210, for example, in which via structures of a given level are generally narrower than the corresponding trace features of the given level.

In addition, the overlapping metal traces of the adjacent or neighboring metal stacks 2231-2237 overlap one another by a non-zero overlap distance 2242. In one implementation, the overlap distance 2242 is greater than the spacing distance 2240. In this or another example, the overlap distance 2242 is greater than or equal to 25 μm. Overlap distances 2242 less than 25 μm can be used but may increase the linearity of crack propagation paths through the insulator material 2217-2219 of the multilevel package substrate 2210. Increasing the overlap distances 2242 can help mitigate or prevent cracks and/or crack propagation in the insulator material 2217-2219, but practical limits to the overlap distances 2242 may arise in specific designs, for example, due to limited X-Y plane spacing requirements for the overall dimensions of the electronic device 2200.

As further shown in FIGS. 22 and 22A, the molded package structure 2208 encloses the semiconductor die 2220 and an upper portion of the multilevel package substrate 2210. In other implementations, the molded package structure 2208 can enclose further portions of the multilevel package substrate 2210, for example, along one or more of the lateral sides 2203-2206. The illustrated example allows solder wicking along exposed side portions of the leads 2224, for example, in QFN or other package types and applications, to facilitate optical inspection of solder joints, etc.

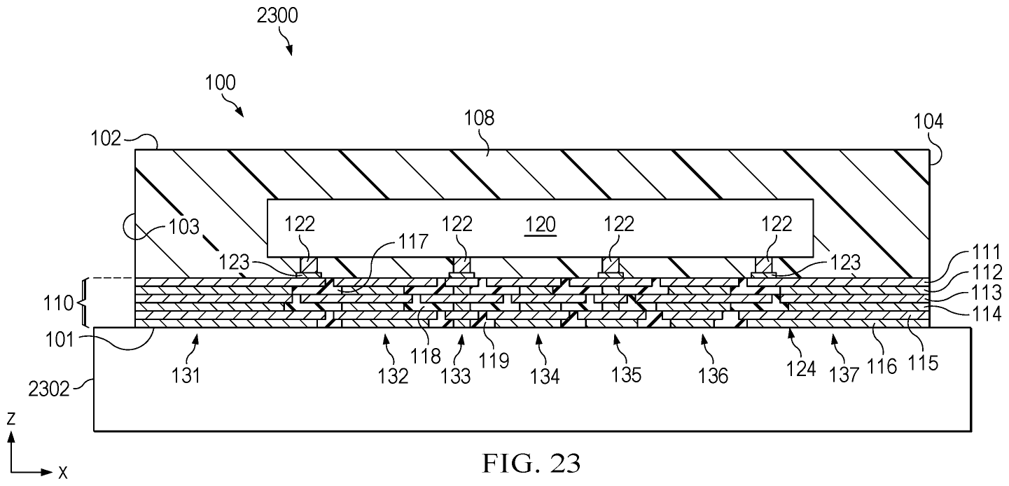

FIG. 23 shows a system 2300 with the electronic device 100 of FIG. 1 soldered to a host printed circuit board 2302. The electronic device 100 in this example is as described above in connection with FIGS. 1 and 1A. Other system examples can include variations of the above described electronic device 100, such as the devices 2000, 2100, and 2200 described above in connection with FIGS. 20-22A. The circuit board 2302 can include one or more routing levels, with traces and vias (not shown) to route electrical signals and/or power to or from the electronic device 100 and between other circuit components of the circuit board 2302 (not shown) to form a system that operates when powered.

Modifications are possible in the described examples, and other implementations are possible, within the scope of the claims.

What is claimed is:

1. An electronic device, comprising:
a multilevel package substrate having a first level, a second level, a first metal stack, and a second metal stack, the first metal stack including a first set of contiguous metal structures of the first and second levels, the second metal stack including a second set of contiguous metal structures of the first and second levels, the first and second metal stacks spaced apart from one another, a first metal trace of the first metal stack partially overlapping a second metal trace of the second metal stack, and the first and second metal traces in different levels of the multilevel package substrate;
a semiconductor die mounted to the multilevel package substrate; and
a package structure that encloses the semiconductor die and a portion of the multilevel package substrate.

2. The electronic device of claim 1, wherein:
the first level extends in a first plane of orthogonal first and second directions;
the second level extends in a second plane of the first and second directions;
the first and second planes are spaced apart from one another along a third direction that is orthogonal to the first and second directions; and
a portion of the first metal trace overlaps a portion of the second metal trace along the third direction.

3. The electronic device of claim 2, wherein:
the metal structures of the first and second metal stacks are spaced apart from one another in the respective first and second planes by a spacing distance;
the first metal trace overlaps the second metal trace by a non-zero overlap distance; and
the overlap distance is greater than the spacing distance.

4. The electronic device of claim 3, wherein the overlap distance is greater than or equal to 25 μm.

5. The electronic device of claim 1, wherein:
the metal structures of the first and second metal stacks are spaced apart from one another by a spacing distance;
the first metal trace overlaps the second metal trace by a non-zero overlap distance; and
the overlap distance is greater than the spacing distance.

6. The electronic device of claim 1, wherein the first metal trace overlaps the second metal trace by a non-zero overlap distance that is greater than or equal to 25 μm.

7. The electronic device of claim 6, wherein the metal structures of the first and second metal stacks are spaced apart from one another by a spacing distance that is greater than or equal to 30 μm and less than 50 μm.

8. The electronic device of claim 1, wherein the metal structures of the first and second metal stacks are spaced apart from one another by a spacing distance that is greater than or equal to 30 μm and less than 50 μm.

9. The electronic device of claim 1, wherein:
the multilevel package substrate has a third level;
the first set of contiguous metal structures of the first metal stack include contiguous metal structures of the first, second, and third levels;
the second set of contiguous metal structures of the second metal stack include contiguous metal structures of the first, second, and third levels;
a third metal trace of the first metal stack partially overlaps the second metal trace of the second metal stack; and
the first, second, and third metal traces are in different levels of the multilevel package substrate.

10. A multilevel package substrate, comprising:
a first level;
a second level;
a first metal stack including a first set of contiguous metal structures of the first and second levels;
a second metal stack including a second set of contiguous metal structures of the first and second levels, the second metal stack spaced apart from the first metal stack;
a first metal trace of the first metal stack partially overlapping a second metal trace of the second metal stack; and
the first and second metal traces in different levels of the multilevel package substrate.

11. The multilevel package substrate of claim 10, wherein:
the first level extends in a first plane of orthogonal first and second directions;
the second level extends in a second plane of the first and second directions;
the first and second planes are spaced apart from one another along a third direction that is orthogonal to the first and second directions; and
a portion of the first metal trace overlaps a portion of the second metal trace along the third direction.

12. The multilevel package substrate of claim 10, wherein:
the metal structures of the first and second metal stacks are spaced apart from one another by a spacing distance;
the first metal trace overlaps the second metal trace by a non-zero overlap distance; and
the overlap distance is greater than the spacing distance.

13. The multilevel package substrate of claim 10, wherein the first metal trace overlaps the second metal trace by a non-zero overlap distance that is greater than or equal to 25 μm.

14. The multilevel package substrate of claim 10, wherein the metal structures of the first and second metal stacks are spaced apart from one another by a spacing distance that is greater than or equal to 30 μm and less than 50 μm.

15. The multilevel package substrate of claim 10, wherein:
the multilevel package substrate has a third level;
the first set of contiguous metal structures of the first metal stack include contiguous metal structures of the first, second, and third levels;
the second set of contiguous metal structures of the second metal stack include contiguous metal structures of the first, second, and third levels;
a third metal trace of the first metal stack partially overlaps the second metal trace of the second metal stack; and
the first, second, and third metal traces are in different levels of the multilevel package substrate.

16. A method of fabricating an electronic device, the method comprising:
fabricating a multilevel package substrate having a first level, a second level, a first metal stack, and a second metal stack, the first metal stack including a first set of contiguous metal structures of the first and second levels, the second metal stack including a second set of contiguous metal structures of the first and second levels, the first and second metal stacks spaced apart from one another, a first metal trace of the first metal stack partially overlapping a second metal trace of the second metal stack, and the first and second metal traces in different levels of the multilevel package substrate.

17. The method of claim 16, further comprising:
attaching a semiconductor die to the multilevel package substrate;
electrically connecting conductive features of the semiconductor die to respective metal traces of the first level of the multilevel package substrate; and
forming a package structure that encloses the semiconductor die and a portion of the multilevel package substrate.

18. The method of claim 16, wherein:
the metal structures of the first and second metal stacks are spaced apart from one another by a spacing distance;
the first metal trace overlaps the second metal trace by a non-zero overlap distance; and
the overlap distance is greater than the spacing distance.

19. The method of claim 16, wherein the metal structures of the first and second metal stacks are spaced apart from one another by a spacing distance that is greater than or equal to 30 μm and less than 50 μm.

20. The method of claim 16, wherein:
the multilevel package substrate has a third level;
the first set of contiguous metal structures of the first metal stack include contiguous metal structures of the first, second, and third levels;
the second set of contiguous metal structures of the second metal stack include contiguous metal structures of the first, second, and third levels;
a third metal trace of the first metal stack partially overlaps the second metal trace of the second metal stack; and
the first, second, and third metal traces are in different levels of the multilevel package substrate.
